(19) United States
(12) Patent Application Publication
(10) Pub. No.: US 2026/0214806 A1
(43) Pub. Date: Jul. 23, 2026

(54) POWER MODULE

(71) Applicant: Mitsubishi Electric Corporation, Tokyo (JP)

(72) Inventors: Kozo HARADA, Chiyoda-ku, Tokyo (JP); Hodaka ROKUBUICHI, Chiyoda-ku, Tokyo (JP)

(73) Assignee: Mitsubishi Electric Corporation, Tokyo (JP)

(21) Appl. No.: 19/144,536

(22) PCT Filed: Jan. 11, 2023
(86) PCT No.: PCT/JP2023/000401

§ 371 Date: Jun. 30, 2025

(51) Int. Cl. H05K 1/183; H05K 1/02; H05K 1/14; H05K 3/36; H10W 90/10

(52) U.S. Cl. CPC H05K 1/183; H05K 1/141; H10W 90/10; H05K 1/0203; H05K 3/368; H05K 2201/042; H05K 2201/10166; H05K 2201/10522; H05K 2201/10636

(57) ABSTRACT

A power module includes: a first substrate having a first surface; a first power semiconductor element mounted on the first surface; a printed substrate having a first facing portion disposed so as to overlap the first surface of the first substrate in a first direction orthogonal to the first surface; and a first conductor post to establish electrical connection between the first power semiconductor element and the first facing portion. A first recess to accommodate the first power semiconductor element and the first conductor post therein is formed in the first facing portion.

### TECHNICAL FIELD

The present disclosure relates to a power module.

### BACKGROUND ART

A power module including a vertical power semiconductor element is used as a power conversion device in a wide range of fields such as industrial equipment, automobiles, and railroads.

In a general power module, an electrode of a power semiconductor element is connected to one end of a lead frame as an external terminal via a bonding wire, and the power semiconductor element, the one end of the lead frame, and the bonding wire are sealed with a resin.

On the other hand, Japanese Patent Laying-Open No. 2009-64852 (PTL 1) discloses a semiconductor device in which a main electrode of a semiconductor element mounted on an insulating substrate and a metal foil of a printed substrate disposed above the semiconductor element are electrically connected via a plurality of post electrodes.

### CITATION LIST

### Patent Literature

PTL 1: Japanese Patent Laying-Open No. 2009-64852

### SUMMARY OF INVENTION

### Technical Problem

In recent years, as equipment including a power module has a higher performance and reduced size and weight, there has been an increasing demand for a reduction in wiring inductance associated with a high-speed switching operation, a reduction in size, and a reduction in thickness, in addition to an increase in rated voltage and rated current of the power module and expansion of an operating temperature range thereof which have been conventionally demanded.

However, in the general power module described above, there is a structural limitation in reducing the length between the electrode of the power semiconductor element and the other end of the lead frame, and thus it is difficult to sufficiently reduce the wiring inductance. Further, in the general power module described above, the electrode of the power semiconductor element and the one end of the lead frame connected via the bonding wire need to be disposed with a spacing therebetween in a plan view, and thus there is also a structural limitation in reducing a dimension in a plan view.

Further, in the semiconductor device described in PTL 1, the insulating substrate, the semiconductor element, the post electrodes, and the printed substrate are disposed side by side in a thickness direction thereof, and thus there is a structural limitation in reducing thickness.

A main object of the present disclosure is to provide a power module in which a reduction in wiring inductance associated with a high-speed switching operation, a reduction in size, and a reduction in thickness are achieved at the same time, relative to a conventional power module.

### Solution to Problem

A power module according to the present disclosure includes: a first substrate having a first surface; a first power semiconductor element mounted on the first surface; a printed substrate having a first facing portion disposed so as to overlap the first surface of the first substrate in a first direction orthogonal to the first surface; and a first conductor post to establish electrical connection between the first power semiconductor element and the first facing portion. A first recess to accommodate the first power semiconductor element and the first conductor post therein is formed in the first facing portion.

### Advantageous Effects of Invention

According to the present disclosure, it is possible to provide a power module in which a reduction in wiring inductance associated with a high-speed switching operation, a reduction in size, and a reduction in thickness are achieved at the same time, relative to a conventional power module.

### BRIEF DESCRIPTION OF DRAWINGS

FIG. 1 is a plan perspective view showing a power module according to a first embodiment.

FIG. 2 is a bottom perspective view showing the power module shown in FIG. 1.

FIG. 3 is a cross sectional view seen from an arrow III-III in FIG. 1.

FIG. 4 is a cross sectional view for illustrating one step of a method for manufacturing the power module shown in FIG. 1.

FIG. 5 is a plan perspective view showing a modification of the power module according to the first embodiment.

FIG. 6 is a cross sectional view for illustrating one step of a method for manufacturing the power module shown in FIG. 5.

FIG. 7 is a plan perspective view showing a power module according to a second embodiment.

FIG. 8 is a bottom perspective view showing the power module shown in FIG. 7.

FIG. 9 is a cross sectional view seen from an arrow IX-IX in FIG. 7.

FIG. 10 is a cross sectional view for illustrating one step of a method for manufacturing the power module shown in FIG. 7.

FIG. 11 is a cross sectional view showing a power module according to a third embodiment.

FIG. 12 is a cross sectional view for illustrating a semiconductor package included in the power module shown in FIG. 11.

FIG. 13 is a cross sectional view showing a power module according to a fourth embodiment.

FIG. 14 is a cross sectional view showing a modification of the power module according to the fourth embodiment.

FIG. 15 is a cross sectional view showing a power module according to a fifth embodiment.

FIG. 16 is a cross sectional view showing a power module according to a sixth embodiment.

FIG. 17 is a cross sectional view showing a modification of the power module according to the sixth embodiment.

FIG. 18 is a cross sectional view showing a power module according to a seventh embodiment.

FIG. 19 is a cross sectional view showing a power module according to an eighth embodiment.

FIG. 20 is a plan perspective view showing a power module according to Comparative Example 1.

FIG. 21 is a cross sectional view showing Comparative Example 1 shown in FIG. 20.

FIG. 22 is a plan perspective view showing a power module according to Comparative Example 2.

FIG. 23 is a cross sectional view showing Comparative Example 2 shown in FIG. 22.

FIG. 24 is a plan perspective view showing a power module according to Comparative Example 3.

FIG. 25 is a cross sectional view showing Comparative Example 3 shown in FIG. 24.

FIG. 26 is a plan perspective view showing a power module according to Comparative Example 4.

FIG. 27 is a cross sectional view showing Comparative Example 4 shown in FIG. 26.

### DESCRIPTION OF EMBODIMENTS

Hereinafter, embodiments of the present disclosure will be described with reference to the drawings. It should be noted that, in the following, identical or corresponding parts will be designated by the same reference numerals, and redundant description will not be repeated.

### First Embodiment

### <Configuration of Power Module>

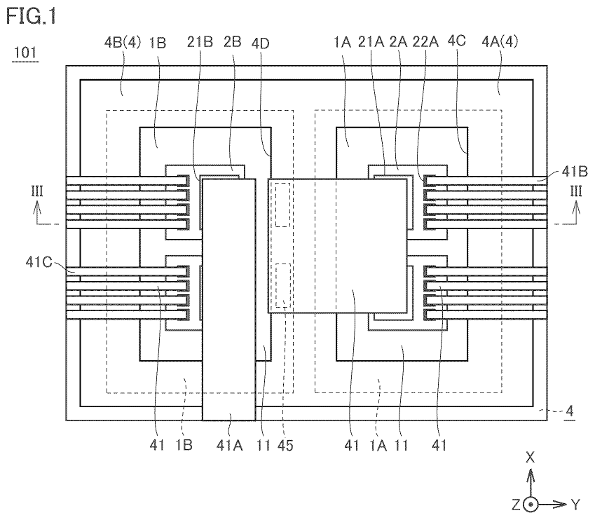

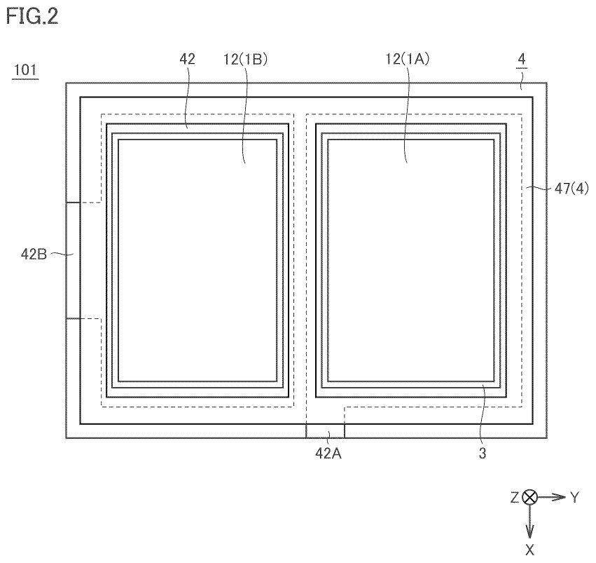

As shown in FIGS. 1 and 2, a power module 101 according to a first embodiment includes a first insulating substrate 1A (a first substrate), a second insulating substrate 1B (a second substrate), a first power semiconductor element 2A, a second power semiconductor element 2B, a plurality of first conductor posts 3A, a plurality of second conductor posts 3B, and a printed substrate 4.

First insulating substrate 1A has a first surface 1A1 on which first power semiconductor element 2A is mounted. In the present specification, a direction orthogonal to first surface 1A1 is referred to as a first direction Z. First insulating substrate 1A includes a base material 10, a first conductor layer 11, and a second conductor layer 12. First conductor layer 11 and second conductor layer 12 are disposed so as to sandwich base material 10 therebetween in first direction Z. Each of first conductor layer 11 and second conductor layer 12 is bonded to base material 10, for example. First surface 1A1 is constituted by a surface of first conductor layer 11 of first insulating substrate 1A opposite to a surface bonded to base material 10.

The material constituting base material 10 may be any material having electrical insulation properties. Base material 10 is a ceramic plate, for example. The material constituting first conductor layer 11 and second conductor layer 12 may be any material having electrical conductivity, and is a metal material, for example.

Second insulating substrate 1B has a second surface 1B1 on which second power semiconductor element 2B is mounted. Second insulating substrate 1B has the same configuration as that of first insulating substrate 1A, for example. Second insulating substrate 1B includes base material 10, first conductor layer 11, and second conductor layer 12. Second surface 1B1 is constituted by a surface of first conductor layer 11 of second insulating substrate 1B opposite to a surface bonded to base material 10.

First insulating substrate 1A and second insulating substrate 1B are disposed side by side with each other in the first direction along first surface 1A1. In power module 101, second surface 1B1 faces the same side as a side which first surface 1A1 faces.

First power semiconductor element 2A and second power semiconductor element 2B are vertical power semiconductor elements, for example. First power semiconductor element 2A and second power semiconductor element 2B are insulated gate bipolar transistors (IGBTs), metal oxide semiconductor field effect transistors (MOSFETs), bipolar transistors, or freewheeling diodes, for example. First power semiconductor element 2A and second power semiconductor element 2B are semiconductor elements of the same type, for example. It should be noted that first power semiconductor element 2A and second power semiconductor element 2B may be semiconductor elements of different types.

First power semiconductor element 2A has a back surface facing a first insulating substrate 1A side in first direction Z, and a front surface located opposite to the back surface and facing a printed substrate 4 side in first direction Z. A back surface electrode (not shown) is formed on the back surface of first power semiconductor element 2A. The back surface electrode is bonded to first conductor layer 11 of first insulating substrate 1A via a bonding material 5. A main electrode 21A and a control electrode 22A are formed on the front surface of first power semiconductor element 2A. Each of main electrode 21A and control electrode 22A of first power semiconductor element 2A is electrically connected with first conductor post 3A. Main electrode 21A is electrically connected with a first wiring layer 41 of printed substrate 4 described later, via first conductor post 3A. Control electrode 22A is electrically connected to first wiring layer 41 of printed substrate 4 described later, via first conductor post 3A.

Second power semiconductor element 2B has a back surface facing a second insulating substrate 1B side in first direction Z, and a front surface located opposite to the back surface and facing the printed substrate 4 side in first direction Z. A back surface electrode (not shown) is formed on the back surface of second power semiconductor element 2B. The back surface electrode is bonded to first conductor layer 11 of second insulating substrate 1B via bonding material 5. For example, a main electrode 21B and a control electrode 22B are formed on the front surface of second power semiconductor element 2B. Each of main electrode 21B and control electrode 22B of second power semiconductor element 2B is electrically connected with second conductor post 3B. Main electrode 21B is electrically connected with first wiring layer 41 of printed substrate 4 described later, via second conductor post 3B. Control electrode 22B is electrically connected to first wiring layer 41 of printed substrate 4 described later, via second conductor post 3B.

Each of the plurality of first conductor posts 3A and the plurality of second conductor posts 3B is a columnar body extending along first direction Z. The material constituting each of the plurality of first conductor posts 3A and the plurality of second conductor posts 3B may be any material having electrical conductivity.

One end in first direction Z of each of the plurality of first conductor posts 3A is bonded to main electrode 21A or control electrode 22A of first power semiconductor element 2A, via a bonding material (not shown) such as solder. The other end in first direction Z of each of the plurality of first conductor posts 3A is bonded to first wiring layer 41 of printed substrate 4 described later, via the bonding material (not shown) such as solder.

One end in first direction Z of each of the plurality of second conductor posts 3B is bonded to main electrode 21B or control electrode 22B of second power semiconductor element 2B, via the bonding material (not shown) such as solder. The other end in first direction Z of each of the plurality of second conductor posts 3B is bonded to first wiring layer 41 of printed substrate 4 described later, via the bonding material (not shown) such as solder.

Printed substrate 4 includes first wiring layer 41, a second wiring layer 42, an insulator layer 44, a through via 45, and a first protective layer 46 and a second protective layer 47. First protective layer 46, first wiring layer 41, insulator layer 44, second wiring layer 42, and second protective layer 47 are stacked in the described order in first direction Z. First wiring layer 41 includes a plurality of patterns that are disposed to be spaced apart from each other on the same plane orthogonal to first direction Z and are electrically isolated from each other. The patterns of first wiring layer 41 are formed by patterning the same conductor layer, and are electrically isolated from each other. Second wiring layer 42 includes a plurality of patterns that are disposed to be spaced apart from each other on the same plane orthogonal to first direction Z and are electrically isolated from each other. The patterns of second wiring layer 42 are formed by patterning the same conductor layer. First wiring layer 41 and second wiring layer 42 are electrically connected via through via 45. First protective layer 46 and second protective layer 47 are provided to protect surfaces of first wiring layer 41 and second wiring layer 42. Through via 45 is formed so as to entirely fill a through hole penetrating insulator layer 44, for example. Through via 45 is a metal material press-fitted into the through hole of insulator layer 44, for example. It should be noted that through via 45 may be a metal thin film formed by plating on a wall surface of the through hole of insulator layer 44. First protective layer 46 and second protective layer 47 are resist layers, for example. First protective layer 46 includes a portion included in a first facing portion 4A and a portion included in a second facing portion 4B, and is formed such that the both portions are contiguous in a second direction Y and a third direction X. Second protective layer 47 is disposed around a first recess 4C in a plan view.

Printed substrate 4 includes first facing portion 4A disposed so as to overlap first surface 1A1 of first insulating substrate 1A in first direction Z, and second facing portion 4B disposed so as to overlap second surface 1B1 of second insulating substrate 1B in first direction Z. First facing portion 4A is disposed side by side with second facing portion 4B in second direction Y.

First facing portion 4A includes a part of each of first wiring layer 41, second wiring layer 42, insulator layer 44, first protective layer 46, and second protective layer 47. Second facing portion 4B includes another part of each of first wiring layer 41, second wiring layer 42, insulator layer 44, first protective layer 46, and second protective layer 47.

In first facing portion 4A, first recess 4C (a counterbore) to accommodate first power semiconductor element 2A and the plurality of first conductor posts 3A therein is formed. First recess 4C is recessed with respect to a lower surface of first facing portion 4A facing the first insulating substrate 1A side in first direction Z. The lower surface of first facing portion 4A is bonded to first surface 1A1 of first insulating substrate 1A.

First recess 4C has a bottom surface facing first surface 1A1 in first direction Z with first power semiconductor element 2A being interposed therebetween, and wall surfaces protruding from outer peripheral edges of the bottom surface in first direction Z and facing side surfaces of first power semiconductor element 2A and each of the plurality of first conductor posts 3A in each of second direction Y and third direction X. Lower ends of the wall surfaces of first recess 4C are connected to inner peripheral edges of the lower surface of first facing portion 4A. Each of the lower surface of first facing portion 4A and the bottom surface and the wall surfaces of first recess 4C may be a single flat surface or curved surface, or may be an uneven surface formed by connecting a plurality of flat surfaces or curved surfaces with each other.

In first facing portion 4A, it is only necessary that at least first wiring layer 41 and first protective layer 46 are formed on the bottom surface of first recess 4C. For example, another wiring layer stacked on first wiring layer 41 in first direction Z and an insulator layer separating that wiring layer from first wiring layer 41 are not formed on the bottom surface of first recess 4C.

At the bottom surface of first recess 4C, for example, a part of each of first wiring layer 41 and first protective layer 46 is exposed. First wiring layer 41 exposed at the bottom surface of first recess 4C is bonded to the other end in first direction Z of each of the plurality of first conductor posts 3A, via the bonding material such as solder. At each wall surface of first recess 4C, for example, a part of each of insulator layer 44 and second wiring layer 42 is exposed.

At the lower surface of first facing portion 4A, for example, another part of each of insulator layer 44 and second wiring layer 42 is exposed. Second wiring layer 42 exposed at the lower surface of first facing portion 4A is bonded to conductor layer 11 of first insulating substrate 1A, via the bonding material such as solder. In a plan view, second wiring layer 42 exposed at the lower surface of first facing portion 4A is continuously disposed so as to surround the entire periphery of first recess 4C. In a plan view, conductor layer 11 of first insulating substrate 1A is continuously disposed so as to surround the entire periphery of first power semiconductor element 2A. In a plan view, the bonding material to bond second wiring layer 42 and conductor layer 11 is continuously disposed so as to surround the entire peripheries of first power semiconductor element 2A and first recess 4C accommodating it. Thereby, the inside of first recess 4C is enclosed by first insulating substrate 1A and the bonding material.

In second facing portion 4B, a second recess 4D (a counterbore) to accommodate second power semiconductor element 2B and the plurality of second conductor posts 3B therein is formed. Second recess 4D is recessed with respect to a lower surface of second facing portion 4B facing the second insulating substrate 1B side in first direction Z. The lower surface of second facing portion 4B faces second surface 1B1 of second insulating substrate 1B without second power semiconductor element 2B being interposed therebetween. Second recess 4D has a bottom surface facing second surface 1B1 in first direction Z with second power semiconductor element 2B being interposed therebetween, and wall surfaces protruding from outer peripheral edges of the bottom surface in first direction Z and facing side surfaces of second power semiconductor element 2B and each of the plurality of second conductor posts 3B in each of second direction Y and third direction X. Lower ends of the wall surfaces of second recess 4D are connected to inner peripheral edges of the lower surface of second facing portion 4B. Each of the lower surface of second facing portion 4B and the bottom surface and the wall surfaces of second recess 4D may be a single flat surface or curved surface, or may be an uneven surface formed by connecting a plurality of flat surfaces or curved surfaces with each other.

Second facing portion 4B includes first wiring layer 41, second wiring layer 42, insulator layer 44, and first protective layer 46 and second protective layer 47. In second facing portion 4B, first protective layer 46, first wiring layer 41, insulator layer 44, second wiring layer 42, and second protective layer 47 are stacked in the described order in first direction Z.

In second facing portion 4B, it is only necessary that at least first wiring layer 41 and first protective layer 46 are formed on the bottom surface of second recess 4D. For example, another wiring layer stacked on first wiring layer 41 in first direction Z and an insulator layer separating that wiring layer from first wiring layer 41 are not formed on the bottom surface of second recess 4D.

At the bottom surface of second recess 4D, for example, a part of each of first wiring layer 41 and first protective layer 46 is exposed. Each of first wiring layers 41 exposed at the bottom surface of second recess 4D is bonded to the other end in first direction Z of each of the plurality of second conductor posts 3B, via the bonding material such as solder. At each wall surface of second recess 4D, for example, a part of each of insulator layer 44 and second wiring layer 42 is exposed.

At the lower surface of second facing portion 4B, for example, another part of each of insulator layer 44 and second wiring layer 42 is exposed. Second wiring layer 42 exposed at the lower surface of second facing portion 4B is bonded to conductor layer 11 of second insulating substrate 1B, via the bonding material such as solder. In a plan view, second wiring layer 42 exposed at the lower surface of second facing portion 4B is continuously disposed so as to surround the entire periphery of second recess 4D. In a plan view, conductor layer 11 of second insulating substrate 1B is continuously disposed so as to surround the entire periphery of second power semiconductor element 2B. In a plan view, the bonding material to bond second wiring layer 42 and conductor layer 11 is continuously disposed so as to surround the entire peripheries of second power semiconductor element 2B and second recess 4D accommodating it. Thereby, the inside of second recess 4D is enclosed by second insulating substrate 1B and the bonding material.

The insides of first recess 4C and second recess 4D are filled with a gas such as air, for example.

A part of first wiring layer 41 of printed substrate 4 is exposed from first protective layer 46 and second protective layer 47 to form a first external connection terminal 41A to be connected to an external device in power module 101. Parts of first wiring layer 41 are exposed from first protective layer 46 and second protective layer 47 to form second external connection terminals 41B and 41C to be connected to external devices in power module 101. Second external connection terminals 41A and 41B are control external terminals. Parts of second wiring layer 42 of printed substrate 4 are exposed from first protective layer 46 and second protective layer 47 to form third external connection terminals 42A and 42B to be connected to external devices in power module 101.

It should be noted that, although solder is exemplified as each bonding material included in power module 101 in the present embodiment, the bonding material is not limited thereto. Sintered silver, a conductive adhesive, a liquid bath diffusion bonding technique, or the like may be used to bond members included in power module 101.

Next, a flow of a main electrical signal in power module 101 will be described. Firstly, a signal inputted to third external connection terminal 42A flows through second wiring layer 42 and conductor layer 11 of first insulating substrate 1A to reach the back surface electrode of first power semiconductor element 2A, and is outputted from main electrode 21A of first power semiconductor element 2A. The signal outputted from main electrode 21A of first power semiconductor element 2A flows through first conductor post 3A, first wiring layer 41, through via 45, and conductor layer 11 of second insulating substrate 1B to reach the back surface electrode of second power semiconductor element 2B, and is outputted from main electrode 21B of second power semiconductor element 2B. The signal outputted from main electrode 21B of second power semiconductor element 2B flows through second conductor post 3B and first wiring layer 41 to reach first external connection terminal 41A, and is outputted to an external device.

Further, a control signal from an external device is inputted to control electrodes 22A and 22B of first power semiconductor element 2A and second power semiconductor element 2B, respectively, via second external connection terminals 41B and 41C, first wiring layer 41, and first conductor post 3A or second conductor post 3B.

### <Method for Manufacturing Power Module>

Hereinafter, an example of a method for manufacturing power module 101 will be described with reference to FIG. 4. As shown in FIG. 4, firstly, a first semifinished product 201, a second semifinished product 202, and printed substrate 4 are prepared.

First semifinished product 201 is an integrated product of first insulating substrate 1A, first power semiconductor element 2A, and the plurality of first conductor posts 3A. In first semifinished product 201, first power semiconductor element 2A is bonded to conductor layer 11 of first insulating substrate 1A by solder or the like, and each of the plurality of first conductor posts 3A is bonded to main electrode 21A or control electrode 22A of first power semiconductor element 2A by solder or the like.

Second semifinished product 202 is an integrated product of second insulating substrate 1B, second power semiconductor element 2B, and the plurality of second conductor posts 3B. In second semifinished product 202, second power semiconductor element 2B is bonded to conductor layer 11 of second insulating substrate 1B by solder or the like, and each of the plurality of second conductor posts 3B is bonded to main electrode 21B or control electrode 22B of second power semiconductor element 2B by solder or the like.

Printed substrate 4 includes first facing portion 4A and second facing portion 4B. First facing portion 4A is a portion expected to be disposed so as to overlap first surface 1A1 of first insulating substrate 1A in first direction Z. Second facing portion 4B is a portion expected to be disposed so as to overlap second surface 1B1 of second insulating substrate 1B in first direction Z.

First recess 4C is formed in first facing portion 4A. At the bottom surface of first recess 4C, for example, a part of each of first wiring layer 41 and first protective layer 46 is exposed. At each wall surface of first recess 4C, for example, a part of each of insulator layer 44 and a third wiring layer is exposed. At the lower surface of first facing portion 4A, for example, another part of each of insulator layer 44 and the third wiring layer is exposed. In a plan view, second wiring layer 42 exposed at the lower surface of first facing portion 4A is continuously disposed so as to surround the entire periphery of first recess 4C. In a plan view, conductor layer 11 of first insulating substrate 1A is continuously disposed so as to surround the entire periphery of first power semiconductor element 2A.

Second recess 4D is formed in second facing portion 4B. At the bottom surface of second recess 4D, for example, a part of each of first wiring layer 41 and first protective layer 46 is exposed. At each wall surface of second recess 4D, for example, a part of each of insulator layer 44 and the third wiring layer is exposed. At the lower surface of second facing portion 4B, for example, another part of each of insulator layer 44 and the third wiring layer is exposed. In a plan view, second wiring layer 42 exposed at the lower surface of second facing portion 4B is continuously disposed so as to surround the entire periphery of second recess 4D. In a plan view, conductor layer 11 of second insulating substrate 1B is continuously disposed so as to surround the entire periphery of second power semiconductor element 2B.

Secondly, a bonding material such as solder is continuously disposed on conductor layer 11 so as to surround the entire periphery of first power semiconductor element 2A. Furthermore, the bonding material such as solder is disposed on main electrode 21A and control electrode 22A of first power semiconductor element 2A. Similarly, the bonding material such as solder is continuously disposed on conductor layer 11 so as to surround the entire periphery of second power semiconductor element 2B. The bonding material such as solder is disposed on main electrode 21B and control electrode 22B of second power semiconductor element 2B.

Thirdly, as shown in FIG. 4, first facing portion 4A is disposed so as to overlap first surface 1A1 of first insulating substrate 1A in first direction Z, and second facing portion 4B is disposed so as to overlap second surface 1B1 of second insulating substrate 1B in first direction Z. On this occasion, first recess 4C is disposed so as to overlap first power semiconductor element 2A and the plurality of first conductor posts 3A in first direction Z. Furthermore, second recess 4D is disposed so as to overlap second power semiconductor element 2B and the plurality of second conductor posts 3B in first direction Z.

Thereafter, as indicated by arrows in FIG. 4, first semifinished product 201 and second semifinished product 202 relatively move with respect to printed substrate 4 in first direction Z. Furthermore, each of the plurality of first conductor posts 3A is bonded to first wiring layer 41 exposed at the bottom surface of first recess 4C by the bonding material, and conductor layer 11 of first insulating substrate 1A is bonded to second wiring layer 42 exposed at the lower surface of first facing portion 4A by the bonding material. Furthermore, each of the plurality of second conductor posts 3B is bonded to first wiring layer 41 exposed at the bottom surface of second recess 4D by the bonding material, and conductor layer 11 of second insulating substrate 1B is bonded to second wiring layer 42 exposed at the lower surface of second facing portion 4B by the bonding material.

In this manner, first semifinished product 201 and second semifinished product 202 are integrated with printed substrate 4. First recess 4C is enclosed by first insulating substrate 1A and the bonding material. Second recess 4D is enclosed by second insulating substrate 1B and the bonding material. First power semiconductor element 2A and the plurality of first conductor posts 3A are accommodated in first recess 4C. Second power semiconductor element 2B and the plurality of second conductor posts 3B are accommodated in second recess 4D.

### <Effect of Power Module>

The effect of power module 101 will be described based on a comparison with a power module according to a comparative example.

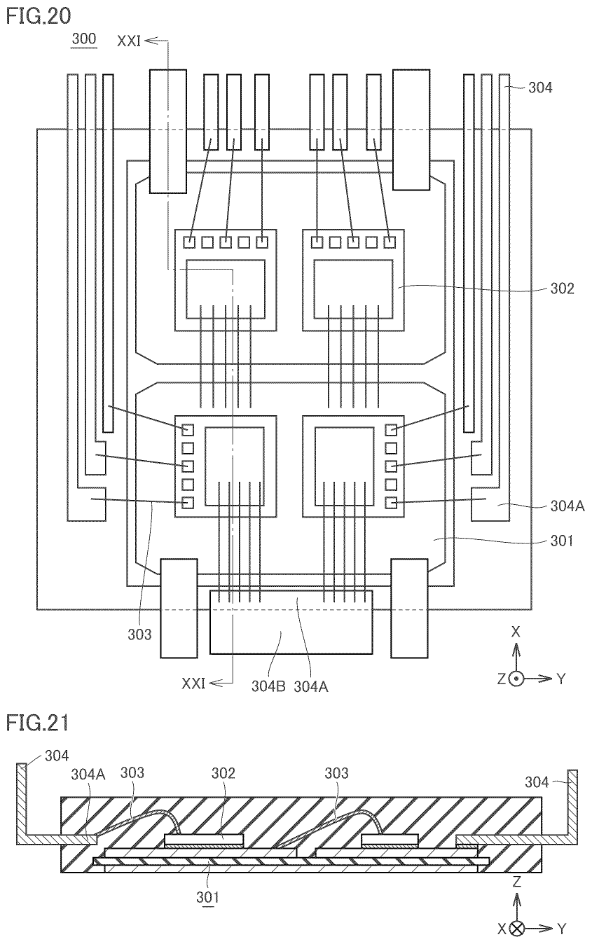

A power module 300 according to Comparative Example 1 shown in FIGS. 20 and 21 includes a plurality of insulating substrates 301, a plurality of power semiconductor elements 302, a plurality of bonding wires 303, and a plurality of lead frames 304. Each bonding wire 303 establishes electrical connection between power semiconductor element 302 and a conductor layer of insulating substrate 301, or between power semiconductor element 302 and lead frame 304. Further, since the plurality of lead frames 304 are generally manufactured by punching a metal plate made of copper or iron, inner leads 304A serving as regions where bonding wires 303 are to be bonded in the plurality of lead frames 304 are disposed on the same plane. In power module 300 including such a plurality of lead frames 304, each lead frame 304 is disposed so as not to overlap power semiconductor element 302 in a plan view, and a portion 304B forming an external connection terminal in each of the plurality of lead frames 304 is disposed more outward than inner lead 304A in a plan view. Accordingly, it is difficult to reduce the area of power module 300 in a plan view.

Further, in power module 300, an electrical path between a power semiconductor element and an external connection terminal is long, because it includes bonding wire 303 and lead frame 304 connected in series with each other. Accordingly, it is difficult to reduce a wiring inductance L of power module 300.

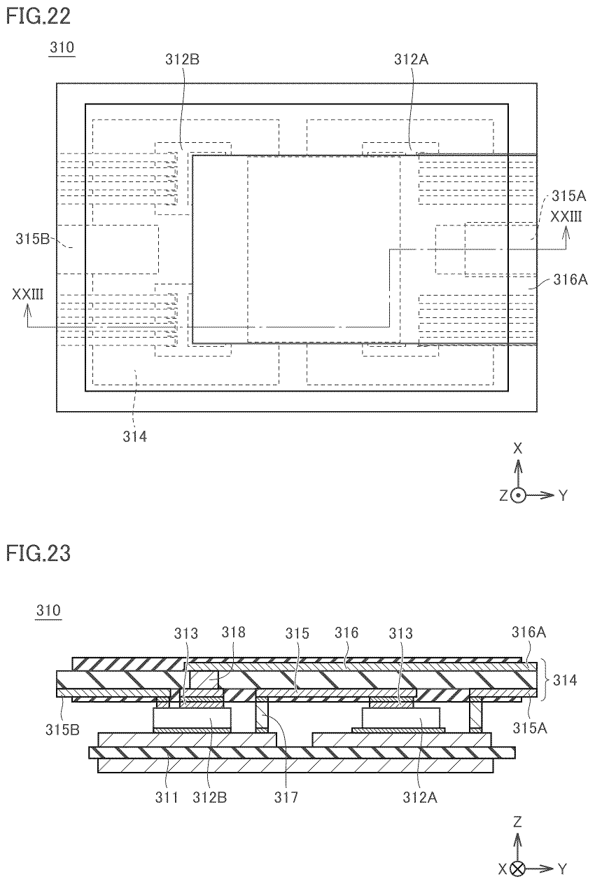

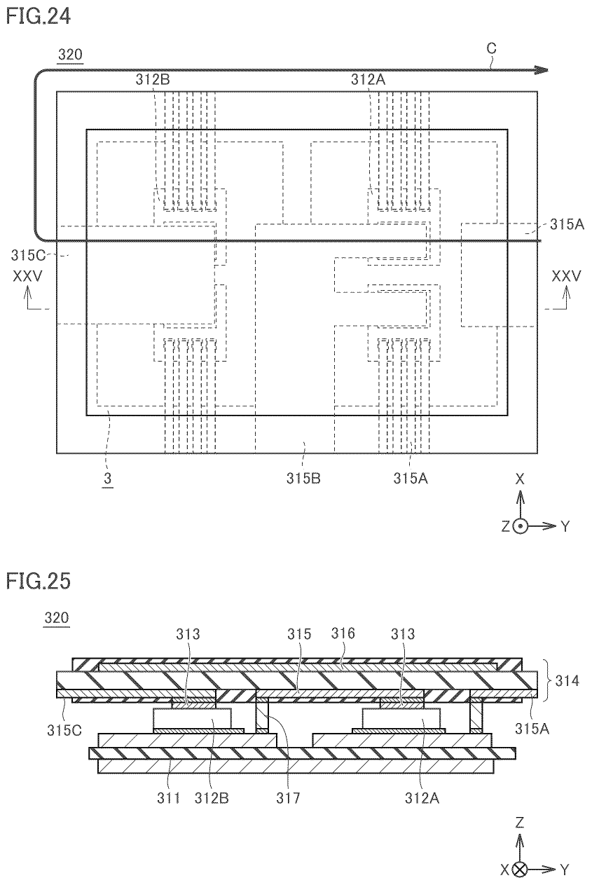

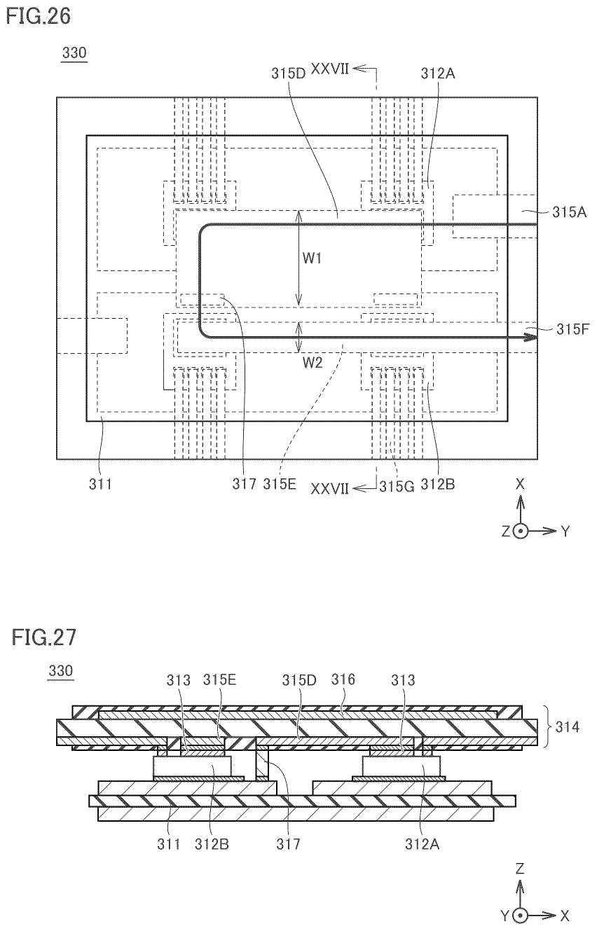

Each of a power module 310 according to Comparative Example 2 shown in FIGS. 22 and 23, a power module 320 according to Comparative Example 3 shown in FIGS. 24 and 25, and a power module 330 according to Comparative Example 4 shown in FIGS. 26 and 27 includes an insulating substrate 311, a first power semiconductor element 312A, a second power semiconductor element 312B, conductor posts 313, and a printed substrate 314, as in power module 101, but is different from power module 101 in that no recess is formed in printed substrate 314.

In power module 310, a wiring layer 315 in printed substrate 314 forms an external connection terminal, and an electrical path between each power semiconductor element and wiring layer 315 does not include a bonding wire and an inner lead, and instead includes conductor post 313. Conductor post 313 is provided to establish electrical connection between first power semiconductor element 312A or second power semiconductor element 312B and the wiring layer in printed substrate 314 which are disposed so as to overlap each other in a plan view. Accordingly, in power module 310, the length of conductor post 313 can be made shorter than the sum of the lengths of a bonding wire and an inner lead, and wiring inductance L can be lower than that of power module 300.

On the other hand, in power module 310, entire printed substrate 314 is disposed on power semiconductor elements 312. Accordingly, it is difficult to reduce a dimension of power module 310 in first direction Z, and in some cases, the dimension of power module 310 in first direction Z is larger than that of power module 300.

Further, power module 310 also requires a conductor block 317 for establishing electrical connection between insulating substrate 311 and wiring layer 315 of printed substrate 314 which face each other without power semiconductor elements 312 being interposed therebetween. The length of conductor block 317 in first direction Z is longer than that of conductor post 313, by the thickness of the power semiconductor elements. Accordingly, it is difficult to reduce the manufacturing cost of power module 310.

Furthermore, in power module 310, printed substrate 314 includes a conductor via 318 for establishing electrical connection between wiring layer 315 and a wiring layer 316 which are stacked in first direction Z. Accordingly, the manufacturing cost of power module 310 including conductor block 317 and conductor via 318 at the same time is high.

It should be noted that an external connection terminal 315A corresponding to third external connection terminal 42A of power module 101 and an external connection terminal 316A corresponding to first external connection terminal 41A of power module 101 are disposed on one end side in second direction Y of power module 310 in a plan view. In power module 310, external connection terminal 315A, conductor block 317, a first conductor layer of insulating substrate 314, power semiconductor element 312A, wiring layer 315, conductor block 317, a second conductor layer of insulator layer 314, power semiconductor element 312B, conductor via 318, wiring layer 316, and external connection terminal 316A are electrically connected in sequence.

Power module 320 according to Comparative Example 3 shown in FIGS. 24 and 25 is different from power module 310 in that printed substrate 314 does not include conductor via 318. Inside such power module 320, only a part of a current path formed inside power module 310 is formed, and the remaining part of the current path needs to be formed outside power module 320. An arrow C in FIG. 24 schematically indicates a current path inside power module 320. In power module 320, an external connection terminal 315C for connection to an external wiring forming the remaining part of the current path is disposed on an end side opposite to external connection terminal 315A corresponding to third external connection terminal 42A of power module 101. In power module 310, external connection terminal 315A, conductor block 317, the first conductor layer of insulating substrate 314, power semiconductor element 312A, wiring layer 315, conductor block 317, the second conductor layer of insulator layer 314, power semiconductor element 312B, wiring layer 315, and external connection terminal 315C are electrically connected in sequence. Accordingly, the sum of the lengths of the current path inside power module 320 and the external wiring is longer than the length of a current path which establishes electrical connection between external connection terminal 315A and external connection terminal 316A in power module 310.

Power module 330 according to Comparative Example 4 shown in FIGS. 26 and 27 is different from power module 310 in that printed substrate 314 does not include conductor via 318. Furthermore, power module 330 is also different from power module 320 in that a current path equivalent to the current path formed inside power module 310 is formed therein. An arrow C shown in FIGS. 26 and 27 schematically indicates a current path inside power module 330. In power module 330, external connection terminal 315A, conductor block 317, the first conductor layer of insulating substrate 314, power semiconductor element 312A, a wiring layer 315D, conductor block 317, the second conductor layer of insulator layer 314, power semiconductor element 312B, a wiring layer 315E, and an external connection terminal 315F are electrically connected in sequence.

In power module 330, it is difficult to reduce a dimension W1 of wiring layer 315D that forms a part of a current path between first power semiconductor element 312A and second power semiconductor element 312B in a direction in which first power semiconductor element 312A and second power semiconductor element 312B are disposed side by side (third direction X in FIG. 26). Furthermore, in power module 330, wiring layer 315D and wiring layer 315E are disposed side by side between a control terminal 315G connected to first power semiconductor element 312A and control terminal 315G connected to second power semiconductor element 312B. Accordingly, it is necessary to increase a dimension of power module 330 in third direction X in order to increase a dimension W2 of wiring layer 315D in third direction X and suppress the wiring inductance to be low.

In contrast, power module 101 includes first conductor posts 3A and second conductor posts 3B instead of bonding wires 303 and lead frames 304, and thus wiring inductance L of power module 101 can be lower than wiring inductance L of power module 300.

Furthermore, in power module 101, another wiring layer stacked on first wiring layer 41 in first direction Z and an insulator layer separating that wiring layer from first wiring layer 41 are not formed on the bottom surface of first recess 4C. Accordingly, in power module 101, the thickness of a partial region of first facing portion 4A disposed so as to overlap first power semiconductor element 2A in first direction Z is thinner than the thickness of printed substrate 314 disposed so as to overlap power semiconductor elements 312A and 312B in power modules 310 to 330.

Accordingly, in power module 101, a reduction in wiring inductance associated with a high-speed switching operation and a reduction in size are achieved at the same time in comparison with power module 300, and a reduction in wiring inductance associated with a high-speed switching operation and a reduction in thickness are achieved at the same time in comparison with power modules 310 to 330.

Furthermore, in power module 101, first recess 4C and second recess 4D are formed in printed substrate 4, and thus power module 101 does not require conductor block 317 required in power modules 310 to 330 in which first recess 4C and second recess 4D are not formed. Accordingly, the manufacturing cost of power module 101 can be reduced in comparison with power modules 310 to 330.

### <Modification>

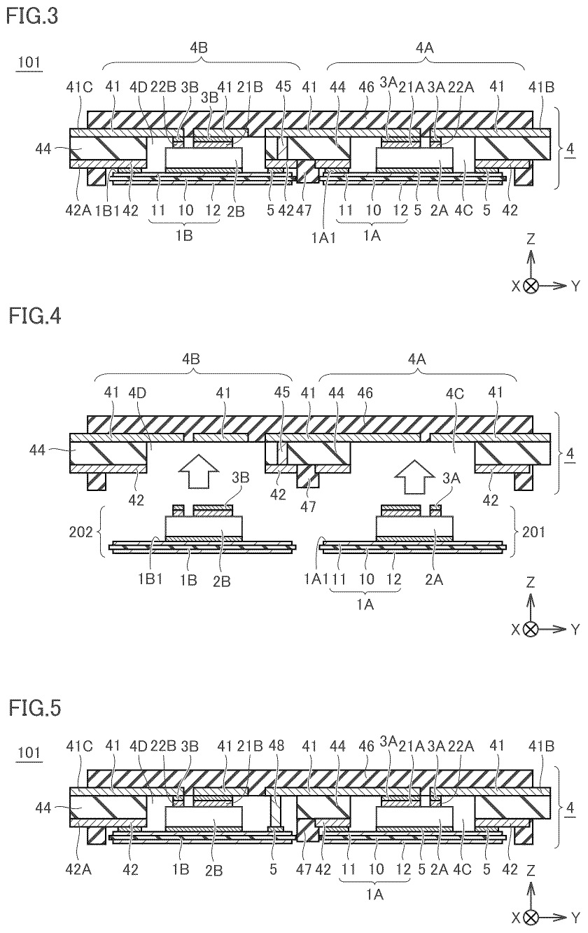

Power module 101 shown in FIG. 5 has basically the same configuration as that of power module 101 shown in FIGS. 1 to 3, but is different from power module 101 shown in FIGS. 1 to 3 in that it has a conductor block 48 and printed substrate 4 not including through via 45, instead of printed substrate 4 including through via 45. Although FIG. 5 shows conductor block 48 only in second recess 4D, it is only necessary that conductor block 48 is disposed inside at least one of first recess 4C and second recess 4D.

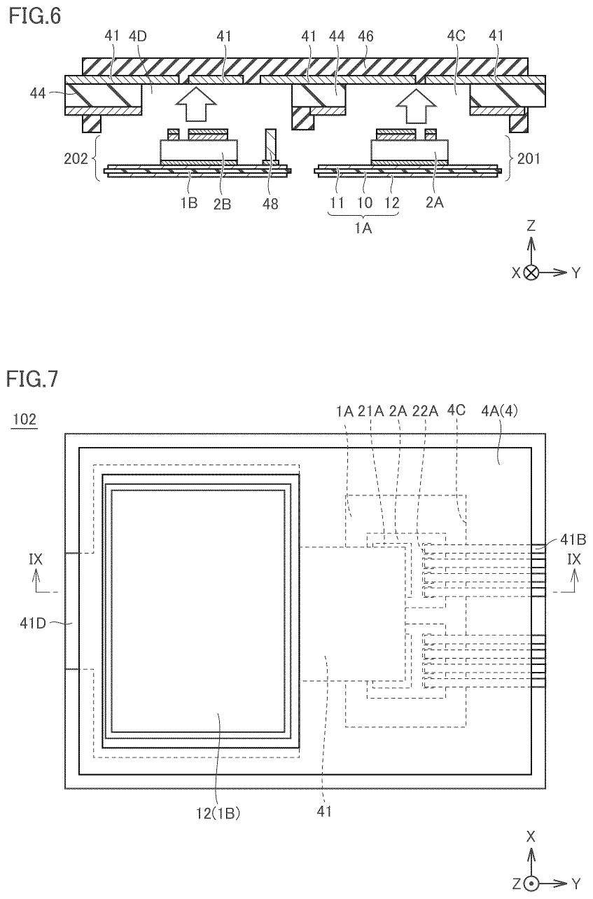

As shown in FIG. 6, in a method for manufacturing power module 101 shown in FIG. 5, second semifinished product 202 including conductor block 48 is prepared, and conductor block 48 is bonded to first wiring layer 41 of printed substrate 4 by a bonding material such as solder.

The manufacturing cost of printed substrate 4 including through via 45 tends to be higher than the sum of the manufacturing cost of printed substrate 4 not including through via 45 and the manufacturing cost of conductor block 48. Specifically, when through via 45 is a columnar metal body press-fitted into the through hole of printed substrate 4 as described above so as to withstand a large current, the manufacturing cost of printed substrate 4 including such through via 45 tends to be extremely higher than that of a printed substrate not including through via 45, and furthermore, tends to be higher than the sum of the manufacturing cost of a printed substrate not including a general conductor via and the manufacturing cost of a conductor block. Accordingly, in power module 101 shown in FIG. 5, the manufacturing cost can be reduced in comparison with power module 101 shown in FIGS. 1 to 3.

It should be noted that, also in power module 101 shown in FIG. 5, a reduction in wiring inductance associated with a high-speed switching operation and a reduction in size are achieved at the same time in comparison with power module 300, and a reduction in wiring inductance associated with a high-speed switching operation and a reduction in thickness are achieved at the same time in comparison with power modules 310 to 330, as in power module 101 shown in FIGS. 1 to 3.

### Second Embodiment

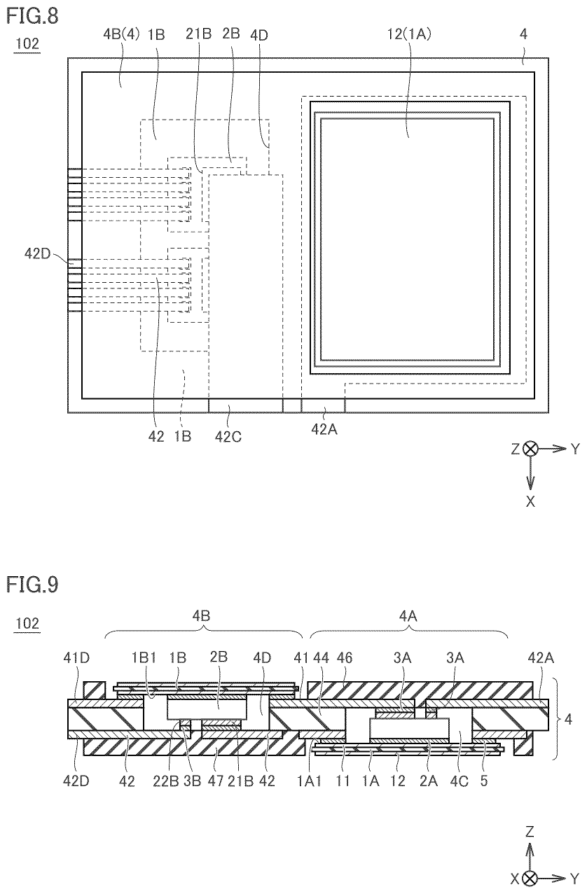

As shown in FIGS. 7 to 9, a power module 102 according to a second embodiment has basically the same configuration as that of power module 101 according to the first embodiment, but is different from power module 101 in that second surface 1B1 of second insulating substrate 1B faces a side opposite to a side which first surface 1A1 of first insulating substrate 1A faces. In the following, the difference between power module 102 and power module 101 will be mainly described.

First recess 4C faces first surface 1A1. Second recess 4D faces second surface 1B1. First protective layer 46 of printed substrate 4 is not included in second facing portion 4B facing second insulating substrate 1B. First protective layer 46 is disposed side by side with second insulating substrate 1B in second direction Y and third direction X. Second protective layer 47 is not included in first facing portion 4A facing first insulating substrate 1A. Second protective layer 47 is disposed side by side with first insulating substrate 1A in second direction Y and third direction X.

Conductor layer 11 of second insulating substrate 1B is bonded to first wiring layer 41 by a bonding material such as solder. Each of main electrode 21B and control electrode 22B of second power semiconductor element 2B is electrically connected with each pattern of second wiring layer 42 via second conductor post 3B. A part of second wiring layer 42 forms an external connection terminal 42C. Another part of second wiring layer 42 forms an external connection terminal 42D as a control external terminal.

Each of first wiring layers 41 is not electrically connected with second wiring layer 42. In other words, printed substrate 4 does not include through via 45 for establishing electrical connection between at least one of first wiring layers 41 and second wiring layer 42.

In power module 102, each of first wiring layers 41 and second wiring layer 42 are electrically connected only via first power semiconductor element 2A or second power semiconductor element 2B. Main electrode 21B of second power semiconductor element 2B is electrically connected with second wiring layer 42 via second conductor post 3B.

As shown in FIG. 9, power module 102 has two-fold rotational symmetry about the center of a cross section orthogonal to third direction X, for example. In this case, the center of power module 102 is located in insulator layer 44 of printed substrate 4.

Next, a flow of a main electrical signal in power module 102 will be described. Firstly, a signal inputted to third external connection terminal 42A flows through second wiring layer 42 and conductor layer 11 of first insulating substrate 1A to reach the back surface electrode of first power semiconductor element 2A, and is outputted from main electrode 21A of first power semiconductor element 2A. The signal outputted from main electrode 21A of first power semiconductor element 2A flows through first conductor post 3A, first wiring layer 41, and conductor layer 11 of second insulating substrate 1B to reach the back surface electrode of second power semiconductor element 2B, and is outputted from main electrode 21B of second power semiconductor element 2B. The signal outputted from main electrode 21B of second power semiconductor element 2B flows through second conductor post 3B and second wiring layer 42 to reach external connection terminal 42C, and is outputted to an external device.

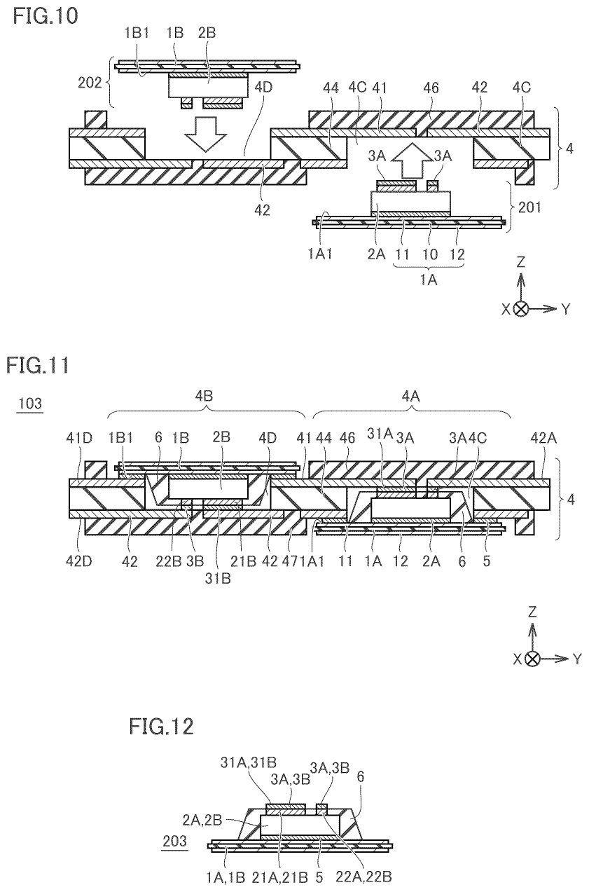

A method for manufacturing power module 102 has basically the same configuration as that of the method for manufacturing power module 101, but is different from the method for manufacturing power module 101 in that, in the method for manufacturing power module 102, as shown in FIG. 10, first semifinished product 201 and second semifinished product 202 are disposed so as to face directions opposite to each other with respect to printed substrate 4. On the other hand, the method for manufacturing power module 102 is the same as the method for manufacturing power module 101 in that first facing portion 4A is disposed so as to overlap first surface 1A1 of first insulating substrate 1A in first direction Z, and second facing portion 4B is disposed so as to overlap second surface 1B1 of second insulating substrate 1B in first direction Z.

Power module 102 can achieve the same effect as that of power module 101. Furthermore, the manufacturing cost of power module 102 having printed substrate 4 not including through via 45 can be reduced in comparison with the manufacturing cost of power module 101 having printed substrate 4 including through via 45. That is, the manufacturing cost of power module 102 can be significantly reduced in comparison with power modules 310 to 330.

### Third Embodiment

As shown in FIG. 11, a power module 103 according to a third embodiment has basically the same configuration as that of power module 102 according to the second embodiment, but is different from power module 102 in that first power semiconductor element 2A is embedded in a resin 6. In the following, the difference between power module 103 and power module 102 will be mainly described.

Second power semiconductor element 2B may also be embedded in resin 6 different from resin 6 in which first power semiconductor element 2A is embedded.

Each first conductor post 3A has an exposed portion 31A exposed from resin 6 formed so as to cover first power semiconductor element 2A. Each second conductor post 3B has an exposed portion 31B exposed from resin 6 formed so as to cover second power semiconductor element 2B. Exposed portions 31A and 31B include upper surfaces of first conductor post 3A and second conductor post 3B, respectively, for example. Exposed portion 31A is electrically connected with first wiring layer 41 of first facing portion 4A via a bonding material (not shown). Exposed portion 31B is electrically connected with second wiring layer 42 of second facing portion 4B via the bonding material (not shown). The bonding material (not shown) is not embedded in resin 6.

In power module 103, it is only necessary that at least one of first power semiconductor element 2A and second power semiconductor element 2B is embedded in the resin. Each of first conductor post 3A and second conductor post 3B may be entirely exposed from resin 6.

The material constituting resin 6 may be any resin material having electrical insulation properties. Resin 6 formed so as to cover first power semiconductor element 2A is not in contact with first wiring layer 41 of first facing portion 4A, for example. Resin 6 formed so as to cover second power semiconductor element 2B is not in contact with second wiring layer 42 of second facing portion 4B, for example.

A method for manufacturing power module 103 has basically the same configuration as that of the method for manufacturing power module 102, but is different therefrom in that a semifinished product 203 shown in FIG. 12 is prepared instead of each of semifinished products 201 and 202. In semifinished product 203, resin 6 is formed so as to embed entire first power semiconductor element 2A or second power semiconductor element 2B, and portions other than exposed portions 31A or 31B of first conductor posts 3A or second conductor posts 3B.

Semifinished product 203 may include a plurality of first power semiconductor elements 2A or a plurality of second power semiconductor elements 2B.

Preferably, before assembling power module 103 including a plurality of semifinished products 203, a step of inspecting characteristics of the power semiconductor element embedded in resin 6 is performed for each semifinished product 203, and power module 103 is assembled using only semifinished products 203 determined as non-defective products in this step. This eliminates the possibility that power module 103 is determined as a defective product because any power semiconductor element in the plurality of semifinished products 203 is defective in characteristics. In the inspecting step, any inspection may be performed, and a withstand voltage test is performed, for example. In the withstand voltage test for semifinished product 203, a high voltage is applied to the power semiconductor element embedded in resin 6, and thus an appropriate inspection can be performed without generating a discharge in the air.

According to power module 103, since each of first power semiconductor element 2A and second power semiconductor element 2B is embedded in resin 6, each of first power semiconductor element 2A and second power semiconductor element 2B is less likely to be affected by an external environment (humidity or contamination). Therefore, power module 103 has a high reliability.

Furthermore, power module 103 can be manufactured to include only semifinished products 203 confirmed as non-defective products by inspection. Accordingly, in power module 103, reliability and production efficiency can be improved at the same time.

The semiconductor material for each of first power semiconductor element 2A and second power semiconductor element 2B of power module 103 is not particularly limited, and may be silicon carbide (SiC). Although SiC is more expensive than silicon (Si), power module 103 has a high production efficiency as described above, which suppresses an increase in manufacturing cost associated with a case where any power semiconductor element incorporated in power module 103 is determined as defective and thereby a non-defective product other than that is also discarded.

It should be noted that power module 103 may have the same configuration as that of power module 101 according to the first embodiment, except that first power semiconductor element 2A is embedded in resin 6.

### Fourth Embodiment

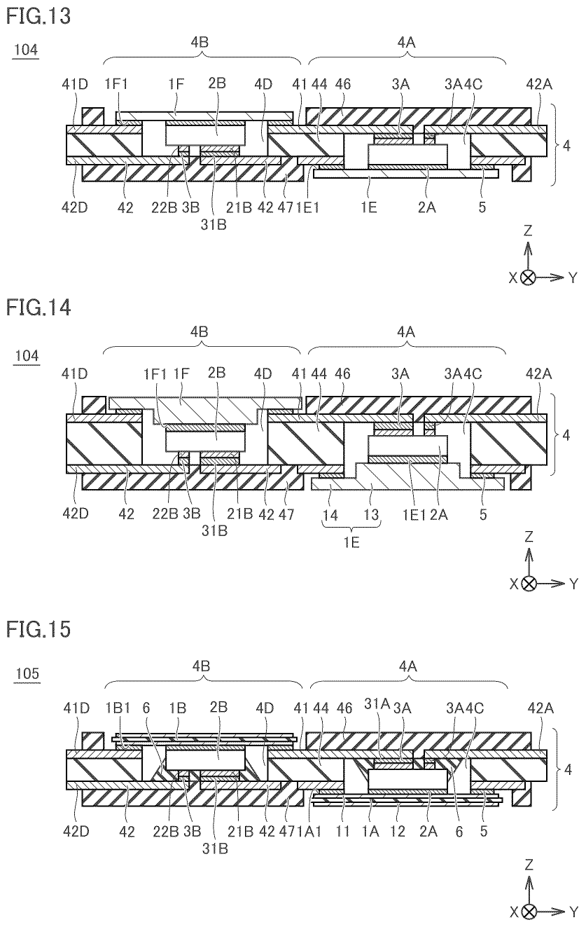

As shown in FIG. 13, a power module 104 according to a fourth embodiment has basically the same configuration as that of power module 102 according to the second embodiment, but is different from power module 102 in that it includes a first conductor plate 1E instead of the first insulating substrate, as the first substrate. In the following, the difference between power module 104 and power module 102 will be mainly described.

The material constituting first conductor plate 1E is a metal material having a high thermal conductivity, for example. First conductor plate 1E is a metal plate acting as a heat spreader, for example. First conductor plate 1E has a first surface 1E1 facing first facing portion 4A. First power semiconductor element 2A is mounted on first surface 1E1.

Power module 104 further includes a second conductor plate 1F as the second substrate, for example. The material constituting second conductor plate 1F may be any metal material, and is a metal material having a high thermal conductivity, for example. Second conductor plate 1F acts as a heat spreader. Second conductor plate 1F has a second surface 1F1 facing second facing portion 4B. Second power semiconductor element 2B is mounted on second surface 1F1.

The thickness of first conductor plate 1E is equal to the thickness of first wiring layer 41 it faces with first power semiconductor element 2A being interposed therebetween, for example. The thickness of second conductor plate 1F is equal to the thickness of second wiring layer 42 it faces with second power semiconductor element 2B being interposed therebetween, for example. Thereby, warpage of power module 104 is reduced. It should be noted that, since each of first conductor plate 1E and second conductor plate 1F is a single metal plate, the thickness thereof is easily adjusted.

Since power module 104 includes first conductor plate 1E which is less expensive than first insulating substrate 1A, the manufacturing cost of power module 104 is lower than those of power modules 101 to 103.

Power module 104 may include second insulating substrate 1B as the second substrate. Further, power module 104 may have the same configuration as that of power module 101 according to the first embodiment, except that it includes first conductor plate 1E instead of the first insulating substrate, as the first substrate.

### <Modification>

As shown in FIG. 14, first conductor plate 1E may include a thick portion 13 and a thin portion 14. Thick portion 13 protrudes more toward the printed substrate 4 side than thin portion 14 in first direction Z. First surface 1E1 is located at a position closest to first facing portion 4A, in a front surface of first conductor plate 1E, as a top surface of thick portion 13. Thin portion 14 is disposed so as to surround the entire periphery of thick portion 13 in a plan view. Thick portion 13 is disposed inside first recess 4C. Preferably, thick portion 13 is formed so as to fit into first recess 4C. Second conductor plate 1F may also include a thick portion and a thin portion. In power module 104 shown in FIG. 14, first recess 4C of printed substrate 4 and first conductor plate 1E are aligned easily, in comparison with power module 103 shown in FIG. 13.

### Fifth Embodiment

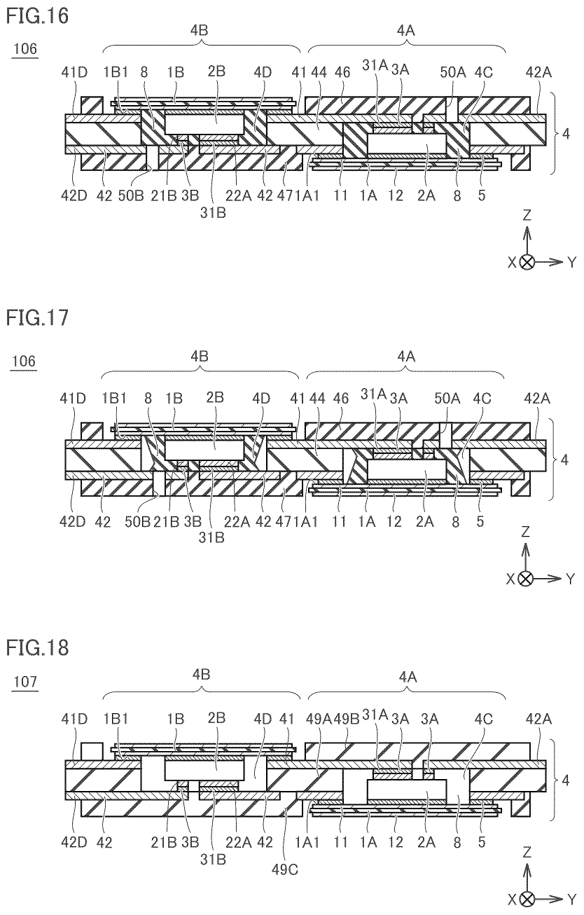

As shown in FIG. 15, a power module 105 according to a fifth embodiment has basically the same configuration as that of power module 102 according to the second embodiment, but is different from power module 105 in that first power semiconductor element 2A, the plurality of first conductor posts 3A, and portions of first facing portion 4A connected to first conductor posts 3A are embedded in a resin 7. In the following, the difference between power module 105 and power module 102 will be mainly described.

In power module 105, first power semiconductor element 2A, the plurality of first conductor posts 3A, portions of first facing portion 4A connected to first conductor posts 3A via a bonding material (not shown), and the bonding material are embedded in resin 7.

Second power semiconductor element 2B, the plurality of second conductor posts 3B, portions of second facing portion 4B connected to second conductor posts 3B via a bonding material (not shown), and the bonding material may also be embedded in resin 7 different from resin 7 in which first power semiconductor element 2A is embedded.

The material constituting resin 7 may be any resin material having electrical insulation properties, and is an underfill resin, for example.

In a method for manufacturing power module 105, firstly, first power semiconductor element 2A in which the plurality of first conductor posts 3A are respectively bonded to main electrode 21A and control electrode 22A, second power semiconductor element 2B in which the plurality of second conductor posts 3B are respectively bonded to main electrode 21B and control electrode 22B, and printed substrate 4 are prepared. First power semiconductor element 2A and second power semiconductor element 2B are not mounted on first insulating substrate 1A or second insulating substrate 1B.

Secondly, first wiring layer 41 of printed substrate 4 and each of the plurality of first conductor posts 3A are bonded by a bonding material (not shown), and second wiring layer 42 and each of the plurality of first conductor posts 3A are bonded by the bonding material (not shown).

Thirdly, resin 7 is formed so as to cover first power semiconductor element 2A, the plurality of first conductor posts 3A, the portions of first facing portion 4A connected to first conductor posts 3A via the bonding material (not shown), and the bonding material, which have been integrated in the previous step. Similarly, resin 7 is formed so as to cover second power semiconductor element 2B, the plurality of second conductor posts 3B, the portions of second facing portion 4B connected to second conductor posts 3B via the bonding material (not shown), and the bonding material. Resin 7 is formed so as to expose the back surface electrode of each of first power semiconductor element 2A and second power semiconductor element 2B.

Fourthly, the back surface electrode of first power semiconductor element 2A exposed from resin 7 and conductor layer 11 of first insulating substrate 1A are bonded by bonding material 5, and the back surface electrode of second power semiconductor element 2B exposed from resin 7 and second insulating substrate 1B are bonded by bonding material 5.

In this manner, power module 105 is manufactured.

In power module 105, since each of first power semiconductor element 2A and second power semiconductor element 2B is embedded in resin 6, each of first power semiconductor element 2A and second power semiconductor element 2B is less likely to be affected by an external environment (humidity or contamination). Therefore, power module 105 has a high reliability.

It should be noted that power module 105 may have the same configuration as that of any of power modules 101, 103, and 104 according to the first, third, and fourth embodiments, except that first power semiconductor element 2A, the plurality of first conductor posts 3A, and the portions of first facing portion 4A connected to first conductor posts 3A are embedded in resin 7.

### Sixth Embodiment

As shown in FIG. 16, a power module 106 according to a sixth embodiment has basically the same configuration as that of power module 102 according to the second embodiment, but is different from power module 102 in that a space between first facing portion 4A and first insulating substrate 1A facing first power semiconductor element 2A and first conductor posts 3A is filled with a resin 8. In the following, the difference between power module 106 and power module 102 will be mainly described.

Resin 8 fills a space formed around first insulating substrate 1A, first power semiconductor element 2A, the plurality of first conductor posts 3A, and the bonding material, inside first recess 4C.

A space formed around second insulating substrate 1B, second power semiconductor element 2B, the plurality of second conductor posts 3B, and the bonding material, inside second recess 4D may also be filled with resin 8.

The material constituting resin 8 is an underfill resin, for example. The material constituting resin 8 has thermosetting properties or ultraviolet curing properties, for example.

A first through hole 50A communicating with the inside of first recess 4C is formed in first facing portion 4A. For example, first through hole 50A is formed so as to penetrate first wiring layer 41 facing the bottom surface of first recess 4C and first protective layer 46.

A second through hole 50B communicating with the inside of second recess 4D is formed in second facing portion 4B. For example, second through hole 50B is formed so as to penetrate second wiring layer 42 facing the bottom surface of second recess 4D and second protective layer 47.

First through hole 50A and second through hole 50B are formed as passages for introducing resin 8 into first recess 4C or second recess 4D.

In a method for manufacturing power module 106, printed substrate 4 in which first through hole 50A and second through hole 50B are formed is prepared. Then, as in the method for manufacturing power module 102, printed substrate 4, first semifinished product 201, and second semifinished product 202 are assembled, and thereafter a liquid curable resin material is introduced into first recess 4C and second recess 4D through first through hole 50A and second through hole 50B, respectively. Then, the liquid curable resin material is cured to form resin 8, and thus power module 106 is manufactured.

In power module 106, since each of first power semiconductor element 2A and second power semiconductor element 2B is embedded in resin 6 as in power module 105, each of first power semiconductor element 2A and second power semiconductor element 2B is less likely to be affected by an external environment (humidity or contamination). Therefore, power module 106 has a high reliability.

Furthermore, in power module 106, since first through hole 50A and second through hole 50B for introducing the material constituting resin 8 into first recess 4C and second recess 4D are formed, resin 8 can be formed after printed substrate 4, first semifinished product 201, and second semifinished product 202 are assembled by the same procedure as that in the method for manufacturing power module 102. Accordingly, power module 106 can be manufactured more easily than power module 105.

Furthermore, in power module 106, since bonding material 5 to bond first insulating substrate 1A and first power semiconductor element 2A is covered with resin 8, breakage of bonding material 5 is suppressed even when power module 106 is placed under a temperature cycle environment. Therefore, power module 106 has a high reliability.

### <Modification>

As shown in FIG. 17, in power module 106, it is only necessary that, inside first recess 4C, at least first power semiconductor element 2A, bonding material 5 to bond first power semiconductor element 2A and first insulating substrate 1A, the plurality of first conductor posts 3A, and the bonding material to bond the plurality of first conductor posts 3A and first facing portion 4A are embedded in resin 8.

Power module 106 may have the same configuration as that of any of power modules 101, 103, and 104 according to the first, third, and fourth embodiments, except that the space between first facing portion 4A and first insulating substrate 1A facing first power semiconductor element 2A and first conductor posts 3A is filled with resin 8.

### Seventh Embodiment

As shown in FIG. 18, a power module 107 according to a seventh embodiment has basically the same configuration as that of power module 102 according to the second embodiment, but is different from power module 106 in that printed substrate 4 is a ceramic substrate. In the following, the difference between power module 107 and power module 102 will be mainly described.

Printed substrate 4 is a ceramic substrate, and includes a base material 49A made of ceramic, and first wiring layer 41 and second wiring layer 42 (conductor layers) stacked on base material 49A. First wiring layer 41 is disposed on one surface of base material 49A. Second wiring layer 42 is disposed on the other surface of base material 49A. Printed substrate 4 may further include a base material 49B and a base material 49C, so as to sandwich base material 49A, first wiring layer 41, and second wiring layer 42 therebetween from first direction Z, for example.

The material constituting base materials 49A, 49B, and 49C includes at least one selected from the group consisting of alumina (Al₂O₃), aluminum nitride (AlN), and silicon nitride (Si₃N₄), for example. Thermal conductivity of such a ceramic material is higher than that of a resin material constituting insulator layer 44.

First recess 4C is formed by a through hole formed in base material 49A, and base material 49B that closes the through hole. Second recess 4D is formed by a through hole formed in base material 49A, and base material 49C that closes the through hole.

Since thermal conductivity of printed substrate 4 of power module 107 is higher than that of printed substrate 4 of power module 102, heat generated in first power semiconductor element 2A is easily released to the outside via printed substrate 4. As a result, power module 107 has a high reliability. Furthermore, since earthquake resistance and impact resistance of printed substrate 4 of power module 107 are higher than those of printed substrate 4 of power module 102, power module 107 has a high reliability even under a more severe environment where high earthquake resistance and impact resistance are required. The range of application of power module 107 is wider than that of power module 102.

Power module 107 may have the same configuration as that of power module 101 according to the first embodiment or any of power modules 103 to 106 according to the third to sixth embodiments, except that printed substrate 4 is a ceramic substrate.

### Eighth Embodiment

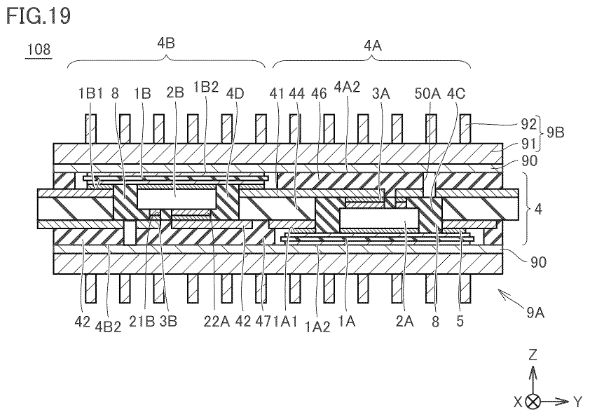

A power module 108 according to the seventh embodiment shown in FIG. 19 has basically the same configuration as that of power module 106 according to the sixth embodiment, but is different from power module 106 in that it further includes a cooler 9A connected to first insulating substrate 1A and a cooler 9B connected to first facing portion 4A. In the following, the difference between power module 108 and power module 106 will be mainly described.

First insulating substrate 1A further has a third surface 1A2 located opposite to first surface 1A1. First facing portion 4A further has a fourth surface 4A2 located opposite to a surface in which first recess 4C is formed. Fourth surface 4A2 is a surface of first protective layer 46.

Second insulating substrate 1B further has a fifth surface 1B2 located opposite to second surface 1B1. Second facing portion 4B further has a sixth surface 4B2 located opposite to a surface in which second recess 4D is formed. Sixth surface 4B2 is a surface of second protective layer 47.

Fifth surface 1B2 is located on the same plane as fourth surface 4A2, for example. Sixth surface 4B2 is located on the same plane as third surface 1A2, for example.

Cooler 9A is connected to third surface 1A2 of first insulating substrate 1A and sixth surface 4B2 of second facing portion 4B, for example. Cooler 9A is bonded to third surface 1A2 and sixth surface 4B2 by a bonding material 90, for example.

Cooler 9B is connected to fifth surface 1B2 of second insulating substrate 1B and fourth surface 4A2 of first facing portion 4A, for example. Cooler 9B is bonded to fifth surface 1B2 and fourth surface 4A2 by bonding material 90, for example.

Each of cooler 9A and cooler 9B may have any structure as long as they can dissipate heat generated in first power semiconductor element 2A and second power semiconductor element 2B to the outside, and is a heat sink including a base portion 91 and a plurality of fins 92 connected to base portion 91, for example. The material constituting cooler 9A and cooler 9B may be any material having a high thermal conductivity, and includes copper (Cu) or aluminum (Al), for example.

The material constituting bonding material 90 may be any bonding material having a thermal conductivity higher than that of the material constituting insulator layer 44 of printed substrate 4. When power module 108 includes first insulating substrate 1A and second insulating substrate 1B as the first substrate and the second substrate, the material constituting bonding material 90 may be a conductive adhesive. Also in such a case, first power semiconductor element 2A can be electrically insulated from cooler 9A, because base material 10 of first insulating substrate 1A constituted by a material having electrical insulation properties is interposed between first power semiconductor element 2A and cooler 9A.

It should be noted that power module 108 only needs to include at least one of cooler 9A and cooler 9B. Further, in power module 108 including cooler 9A and cooler 9B, it is only necessary that cooler 9A is connected to at least a part of first insulating substrate 1A, and cooler 9B is connected to at least a part of second insulating substrate 1B.

Further, power module 108 may have the same configuration as that of any of power modules 101 to 105 according to the first to fifth embodiments and power module 107 according to the seventh embodiment, except that it includes at least one of cooler 9A and cooler 9B. When power module 107 includes first conductor plate 1E as the first substrate as with power module 104, it is only necessary that the material constituting bonding material 90 is selected from materials having electrical insulation properties, and having thermal conductivities higher than that of the material constituting insulator layer 44 of printed substrate 4.

Although the embodiments of the present disclosure have been described above, the above-described embodiments can be variously modified. Further, the scope of the present disclosure is not limited to the above-described embodiments. The scope of the present disclosure is defined by the scope of the claims, and is intended to include any modifications within the scope and meaning equivalent to the scope of the claims.

### REFERENCE SIGNS LIST

1A: first insulating substrate; 1A1, 1E1: first surface; 1A2: third surface; 1B: second insulating substrate; 1B1, 1F1: second surface; 1B2: fifth surface; 1E: first conductor plate; 1F: second conductor plate; 2A: first power semiconductor element; 2B: second power semiconductor element; 3A: first conductor post; 3B: second conductor post; 4: printed substrate; 4A: first facing portion; 4A2: fourth surface; 4B: second facing portion; 4B2: sixth surface; 4C: first recess; 4D: second recess; 5, 90: bonding material; 6, 7, 8: resin; 9A, 9B: cooler; 10, 49A, 49B, 49C: base material; 11: first conductor layer; 12: second conductor layer; 13: thick portion; 14: thin portion; 21A, 21B: main electrode; 22A, 22B: control electrode; 31A, 31B: exposed portion; 41: first wiring layer; 42: second wiring layer; 41A, 41B, 41C, 42A, 42B, 42C, 42D: second external connection terminal; 44: insulator layer; 45: through via; 46: first protective layer; 47: second protective layer; 48: conductor block; 50A: first through hole; 50B: second through hole; 91: base portion; 92: fin; 101, 102, 103, 104, 105, 106, 107, 108, 300, 310, 320, 330: power module; 201, 202, 203: semifinished product.

1. A power module comprising:
a first substrate having a first surface;
a first power semiconductor element mounted on the first surface;
a printed substrate having a first facing portion disposed so as to overlap the first surface of the first substrate in a first direction orthogonal to the first surface; and
a first conductor post to establish electrical connection between the first power semiconductor element and the first facing portion, wherein
a first recess to accommodate the first power semiconductor element and the first conductor post therein is formed in the first facing portion
the first substrate is an insulating substrate including a conductor layer having the first surface,
the first facing portion includes a first wiring layer, a second wiring layer, an insulator layer, a first protective layer, and a second protective layer,
the first protective layer, the first wiring layer, the insulator layer, the second wiring layer, and the second protective layer are stacked in the described order in the first direction,
the second wiring layer of first facing portion is bonded to the conductor layer of first insulating substrate, via a bonding material, and
in a plan view, the second wiring layer, the conductor layer and the bonding material are continuously disposed so as to surround the entire periphery of the first power semiconductor element or the first recess.

2. The power module according to claim 1, comprising:
a second substrate having a second surface; and
a second power semiconductor element mounted on the second surface, wherein
the printed substrate further has a second facing portion disposed so as to overlap the second surface of the second substrate in the first direction,
the power module further comprises a second conductor post to establish electrical connection between the second power semiconductor element and the second facing portion, and
a second recess to accommodate the second power semiconductor element and the second conductor post therein is formed in the second facing portion.
the second surface faces a side opposite to a side which the first surface faces,
the first recess faces the first surface, and
the second recess faces the second surface and is disposed side by side with the first recess in a direction along the first surface.

3.-4. (canceled)

5. The power module according to claim 1, wherein the first substrate is an insulating substrate including the conductor layer and an insulator layer stacked on the conductor layer in the first direction.

6. The power module according to claim 1, wherein the first substrate is a conductor plate having the first surface and a back surface located opposite to the first surface.

7. The power module according to claim 6, wherein
the first substrate includes a thin portion facing the first facing portion of the printed substrate without the first power semiconductor element being interposed therebetween, and a thick portion protruding in the first direction with respect to the thin portion, and
the first surface is a front surface of the thick portion.

8. The power module according to claim 1, wherein
the first power semiconductor element is embedded in a resin,
the first conductor post has an exposed portion exposed from the resin, and
the exposed portion is electrically connected with the first facing portion.

9. The power module according to claim 1, wherein the first power semiconductor element, the first conductor post, and a portion of the first facing portion connected to the first conductor post are embedded in a resin.

10. The power module according to claim 9, wherein a space between the first facing portion and the first substrate facing the first power semiconductor element and the first conductor post is filled with the resin.

11. The power module according to claim 1, wherein the printed substrate is a ceramic substrate including a base material made of ceramics, and a conductor layer stacked on the base material.

12. The power module according to claim 1, wherein
the first substrate further has a third surface located opposite to the first surface in the first direction,
the first facing portion has a fourth surface located opposite to the first recess in the first direction, and
the power module further comprises a cooler connected to the third surface or the fourth surface.

13. The power module according claim 1, wherein
the first facing portion has a facing surface facing the first surface without the first power semiconductor element being interposed therebetween, and
the power module further comprises a bonding member to bond the facing surface and the first surface.

14. The power module according to claim 2, wherein the first substrate is an insulating substrate including the conductor layer and an insulator layer stacked on the conductor layer in the first direction.
